(19) United States
(12) Patent Application Publication
(10) Pub. No.: US 2025/0034719 A1
(43) Pub. Date: Jan. 30, 2025

(54) APPARATUS AND METHOD OF TREATING SUBSTRATE

(71) Applicant: SEMES CO., LTD., Cheonan-si (KR)

(72) Inventors: Pil Kyun HEO, Yongin-si (KR); Ki Moon KANG, Yongin-si (KR); Joon Ho WON, Suwon-si (KR); Byeong Kwan KIM, Hwaseong-si (KR); Hong Chan CHO, Hwaseong-si (KR)

(73) Assignee: SEMES CO., LTD., Cheonan-si (KR)

(21) Appl. No.: 18/754,613

(22) Filed: Jun. 26, 2024

(30) Foreign Application Priority Data
Jul. 28, 2023 (KR) 10-2023-0098609

(51) Int. Cl. C23F 1/08; H01L 21/67

(52) U.S. Cl. CPC C23F 1/08; H01L 21/67017

(57) ABSTRACT

Disclosed is an apparatus for processing a substrate, the apparatus including: a chamber for forming a processing space in which a processing process for a substrate is performed therein by a combination of a first body and a second body; and a driver for moving any one of the first body or the second body relative to the other such that a relative position between the first body and the second body is changeable between a sealed position at which the processing space is sealed from the outside and an open position at which the processing space is opened, in which the first body is formed with a first protrusion on a face that is in contact with the second body, the second body is formed with a first receiving portion, and the first protrusion is provided to be inserted into the first receiving portion when the first body and the second body are at the sealed position.

### CROSS-REFERENCE TO RELATED APPLICATIONS

This application claims priority to and the benefit of Korean Patent Application No. 10-2023-0098609 filed in the Korean Intellectual Property Office on Jul. 28, 2023, the entire contents of which are incorporated herein by reference.

### TECHNICAL FIELD

The present invention relates to an apparatus for processing a substrate and a method of processing a substrate, and more particularly to an apparatus and a method of processing a substrate in a high pressure atmosphere.

### BACKGROUND ART

In order to manufacture a semiconductor device, a desired pattern is formed on a substrate through various processes, such as photography, etching, ashing, ion implantation, and thin film deposition. Various processing liquids are used in each process, and contaminants and particles are generated during the process. To eliminate the contaminants and particles, a cleaning process is essential before and after each process to remove contaminants and particles.

Typically, the cleaning process involves treating the substrate with a chemical and rinse solution, followed by drying. The drying treatment operation is a process for drying the rinse solution remaining on the substrate, which involves replacing the rinse solution on the substrate with an organic solvent with lower surface tension than the rinse solution, such as isopropyl alcohol (IPA), and subsequently removing the organic solvent. However, as the patterns formed on the substrate become finer, it is not easy to remove the organic solvent that remains in the spaces between the patterns.

In recent years, a process of removing the organic solvent residual on the substrate by using a supercritical fluid is performed. The supercritical processing process is carried out in a high-pressure processing space that is sealed from the outside to meet the specific conditions of the supercritical fluid.

After the supercritical processing process is completed, the processing space is opened to unload the substrate. However, due to the expansion of the processing space at the beginning of opening, the pressure in the processing space is temporarily lower than that outside, which causes particles from the outside to enter.

### SUMMARY OF THE INVENTION

The present invention has been made in an effort to provide an apparatus and a method of minimizing the introduction of external particles into a processing space during a process of opening the processing space.

The object of the present invention is not limited thereto, and other objects not mentioned will be clearly understood by those of ordinary skill in the art from the following description.

An exemplary embodiment of the present invention provides an apparatus for processing a substrate, the apparatus including: a chamber including a first body and a second body which are combined with each other to form a processing space in which a processing process for a substrate is performed therein; a driver for moving any one of the first body or the second body relative to the other such that a relative position between the first body and the second body is changeable between a sealed position at which the processing space is sealed from the outside and an open position at which the processing space is opened; a support unit for supporting a substrate in the processing space; and a fluid supply unit for supplying a processing fluid to the processing space; and an exhaust unit for exhausting a fluid from the processing space, in which the first body is formed with a first protrusion on a face that is in contact with the second body, the second body is formed with a first receiving portion, and the first protrusion is provided to be inserted into the first receiving portion when the first body and the second body are at the sealed position.

According to the exemplary embodiment, the first protrusion and the first receiving portion may be formed such that the first protrusion does not contact an inner wall providing the first receiving portion when the first body and the second body are at the sealed position or the open position.

According to the exemplary embodiment, the first protrusions may be formed in plurality along a radial direction of the chamber.

According to the exemplary embodiment, the first protrusion may be provided in a ring shape when viewed from above.

According to the exemplary embodiment, the chamber may further include a sealing member, and the first protrusion may be located further out than the sealing member in a radial direction of the chamber.

According to the exemplary embodiment, the first body may be positioned below the second body, and an upper end of the first protrusion may be formed at a position higher than an upper end of the sealing member.

According to the exemplary embodiment, the second body may be formed with a second protrusion on a face that is in contact with the first body, the first body may be formed with a second receiving portion, and, the second protrusion may be provided to be inserted into the second receiving portion when the first body and the second body are at the sealed position.

According to the exemplary embodiment, the apparatus may further include a clamping member for clamping the chamber when the first body and the second body are at the sealed position.

According to the exemplary embodiment, the apparatus may further include a controller, in which the controller may process the substrate by supplying a first processing gas into the processing space in the state where the processing space is sealed, subsequently, when the processing process for the substrate is completed, supply a purge gas to the processing space until the processing space is at a preset pressure, and subsequently, control the driver to move the first body and the second body relative to each other such that the first body and the second body are spaced apart by a first separation distance, and subsequently, move the first body and the second body relative to each other such that the first body and the second body are separated by a second separation distance, the first separation distance may be a shorter than the second separation distance, and the second separation distance may be a distance that is separated between the first body and the second body when the substrate is loaded into the processing space or unloaded from the processing space.

According to the exemplary embodiment, the first separation distance may be shorter than a height by which the first protrusion protrudes from the first body.

Another exemplary embodiment of the present invention provides a method of processing a substrate, the method including: a loading operation of loading, by a transfer hand, a substrate into an open processing space; a sealing operation of sealing the processing space; a process processing operation of forming the sealed processing space with a pressure greater than normal pressure, and supplying a processing fluid to the processing space to process the substrate loaded into the processing space; an exhausting operation of exhausting atmosphere of the processing space; and an opening operation for opening the processing space, in which the opening operation includes: a first opening operation of opening the processing space by moving the first body and the second body relative to each other such that the a distance between the first body and the second body forming the processing space is a first separation distance; and a second opening operation of opening the processing space by moving the first body and the second body relative to each other such that the a distance between the first body and the second body is a second separation distance that is greater than the first separation distance, and the first separation distance is shorter than a height by which a protrusion formed on a face that is in contact with the second body protrudes from the first body.

According to the exemplary embodiment, the first separation distance may be a shorter than the second separation distance, and the second separation distance may be a distance separated between the first body and the second body when the substrate is loaded into the processing space or unloaded from the processing space.

According to the exemplary embodiment, the method may further include, between the exhausting operation and the opening operation, a gas supply operation of supplying a purge gas to the processing space until the processing space reaches a preset pressure, in which the preset pressure is higher than an external pressure of the processing space.

According to the exemplary embodiment, the gas supply operation may include stopping exhausting atmosphere of the processing space.

According to the exemplary embodiment, a speed at which the first body and the second body move relative to each other in the second opening operation may be less than a speed at which the first body and the second body move relative to each other in the first opening operation.

According to the exemplary embodiment, after the first opening operation, and before the second opening operation, the relative movement of the first body and the second body is stopped for a predetermined period of time.

According to the exemplary embodiment, the method may further include a clamping operation of clamping the processing space after sealing the processing space between the loading operation and the process processing operation; and a clamping releasing operation of releasing the clamping between the exhausting operation and the first opening operation.

Still another exemplary embodiment of the present invention provides an apparatus for processing a substrate, the apparatus including: a chamber including a first body and a second body which are combined with each other to form a processing space in which a processing process for a substrate is performed therein; a driver for moving any one the first body or the second body relative to the other such that a relative position between the first body and the second body is changeable between a sealed position at which the processing space is sealed from the outside and an open position at which the processing space is opened; a support unit for supporting a substrate in the processing space; and a fluid supply unit for supplying a processing fluid to the processing space; an exhaust unit for exhausting a fluid from the processing space; a clamping member for clamping the chamber when the first body and the second body are at the sealed position; and a controller, in which the first body is formed with a protrusion on a face that is in contact with the second body, the second body is formed with a receiving portion, and the protrusion is provided to be inserted into the receiving portion when the first body and the second body are at the sealed position, the controller clamps the chamber in the state where the processing space is sealed, supplies first processing gas to the processing space, supplies purge gas to the processing space until the processing space is at a preset pressure when the processing process for the substrate is completed, and releases the clamping, controls the driver to move the first body and the second body relative to each other such that the first body and the second body are spaced apart by a first separation distance, and the first separation distance is a shorter than a second separation distance, and the second separation distance is a distance separated between the first body and the second body when the substrate is loaded into the processing space or unloaded from the processing space, and the first separation distance is shorter than a height by which the protrusion protrudes from the first body.

According to the exemplary embodiment, the controller may control the driver to move the first body and the second body relative to each other such that the first body and the second body are spaced apart by a first separation distance, and then stop the relative movement of the first body and the second body for a predetermined period of time before moving the first body and the second body relative to each other such that the first body and the second body are spaced apart by the second separation distance.

According to the exemplary embodiment, the chamber may further include a sealing member, and the protrusion may be located further out than the sealing member in a radial direction of the chamber.

According to the exemplary embodiment of the present invention, it is possible to minimize the introduction of external particles and external air currents during the process of opening the processing space.

Furthermore, according to the exemplary embodiment of the present invention, it is possible to prevent the processing space from rapidly expanding and to prevent a negative pressure from being temporarily generated in the processing space in the drying chamber.

The effect of the present invention is not limited to the foregoing effects, and non-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a diagram illustrating a substrate processing apparatus according to an exemplary embodiment of the present invention.

FIG. 2 is a diagram schematically illustrating a liquid treating chamber of FIG. 1 according to an exemplary embodiment.

FIG. 3 is a diagram schematically illustrating a drying chamber of FIG. 1 according to an exemplary embodiment.

FIG. 4 is an enlarged view of a portion where a first body and a second body of FIG. 3 are in contact with each other.

FIG. 5 is a perspective view of a substrate support unit of FIG. 3.

FIG. 6 is a perspective view of a clamping member of FIG. 3.

FIG. 7 is a flowchart illustrating a process of processing a substrate by using the apparatus of FIG. 3.

FIGS. 8 to 19 are drawings illustrating the process of treating the substrate according to each operation of the flowchart of FIG. 7 by using the apparatus of FIG. 3.

FIG. 20 is a graph plotting the gap between the first body and the second body according to each operation of the flowchart of FIG. 7.

FIGS. 21 to 23 are diagrams illustrating a chamber body of the present invention according to modified exemplary embodiments.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

A substrate processing apparatus may perform a supercritical process to treat a substrate W by using a supercritical fluid as a process fluid.

The term “substrate W” is a broad concept that includes any substrate used to manufacture semiconductor devices, Flat Panel Displays (FPDs), and other items having circuit patterns formed on a thin film. Examples of the substrate W include silicon wafers, various wafers, glass substrates, and organic substrates.

The supercritical fluid refers to a phase that has the properties of both gas and liquid formed when it reaches a supercritical state exceeding a critical temperature and critical pressure. The supercritical fluid has molecular density close to that of a liquid and viscosity close to that of a gas, so the supercritical fluid has excellent diffusion, penetration, and solubility, which are favorable for chemical reactions, and has almost no surface tension, so the supercritical fluid does not apply interfacial tension to the microstructure.

A supercritical process is carried out by using the properties of the supercritical fluid, and includes, for example, a supercritical drying process and a supercritical etching process. In the following, the supercritical process will be described based on the supercritical drying process. However, this is for illustrative purposes only, and the substrate processing apparatus may perform other supercritical processes other than the supercritical drying process.

The supercritical drying process may be performed by dissolving the organic solvent residual in a circuit pattern of the substrate W with a supercritical fluid and drying the substrate W, which has the advantage of not only excellent drying efficiency but also preventing collapse phenomenon. As the supercritical fluid utilized in the supercritical drying process, a substance that is miscible with the organic solvent may be used. For example, supercritical carbon dioxide (scCO2) may be used as a supercritical fluid.

Carbon dioxide has a critical temperature of 31.1° C. and a relatively low critical pressure of 7.38 MPa, so that carbon dioxide may be easily made to a supercritical state, and it is easy to control phase change of carbon dioxide by adjusting temperature and pressure, and carbon dioxide is low priced. In addition, carbon dioxide is non-toxic, harmless to humans, non-flammable, and inert, and supercritical carbon dioxide has a diffusion coefficient 10 to 100 times higher than water or other organic solvents, which allows for faster penetration and substitution of organic solvents, and has almost no surface tension, which is advantageous for drying the substrates W with fine circuit patterns. Furthermore, carbon dioxide may be recycled as a by-product of various chemical reactions, and may be used in the supercritical drying process and then converted into gas to separate the organic solvent to be reused, which is less burdensome in terms of environmental pollution.

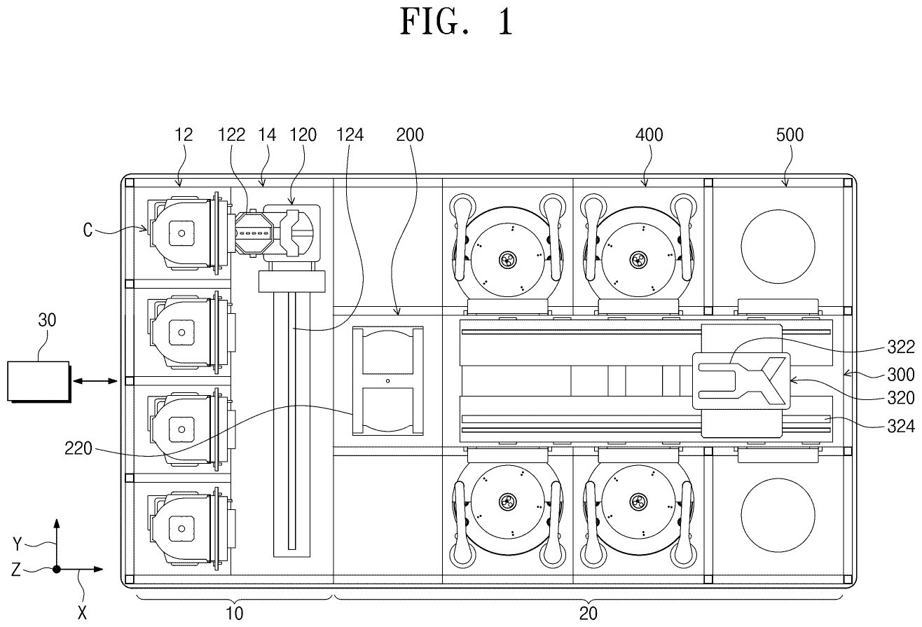

Hereinafter, an exemplary embodiment of the present invention will be described in detail with reference to FIGS. 1 to 15.

FIG. 1 is a diagram illustrating a substrate processing apparatus according to an exemplary embodiment of the present invention.

Referring to FIG. 1, the substrate processing apparatus includes an index module 10, a treating module 20, and a controller 30. When viewed from above, the index module 10 and the treating module 20 are disposed along one direction. Hereinafter, the direction in which the index module 10 and the treating module 20 are arranged is referred to as a first direction X, when viewed from above, a direction perpendicular to the first direction X is referred to as a second direction Y, and a direction perpendicular to both the first direction X and the second direction Y is referred to as a third direction Z.

The index module 10 transfers the substrate W from the container C in which the substrate W is accommodated to the treating module 20, and accommodates the substrate W that has been completely treated in the treating module 20 in the container C. A longitudinal direction of the index module 10 is provided in the second direction Y. The index module 10 includes a load port 12 and an index frame 14. Based on the index frame 14, the load port 12 is located at a side opposite to the treating module 20. The container C in which the substrates W are accommodated is placed in the load port 12. A plurality of load ports 12 may be provided, and the plurality of load ports 12 may be disposed along the second direction Y.

As the container C, an airtight container, such as a Front Open Unified Pod (FOUP), may be used. The container C may be placed on the load port 12 by a transport means (not illustrated), such as an overhead transfer, an overhead conveyor, or an automatic guided vehicle, or an operator.

An index robot 120 is provided to the index frame 14. A guide rail 124 of which a longitudinal direction is provided in the second direction Y is provided in the index frame 14, and the index robot 120 may be provided to be movable on the guide rail 124. The index robot 120 includes a hand 122 on which the substrate W is placed, and the hand 122 may be provided to be movable forward and backward directions, rotatable about the third direction Z and movable along the third direction Z. A plurality of hands 122 are provided to be spaced apart in the vertical direction, and the hands 122 may move forward and backward independently of each other.

The controller 30 may control the substrate processing apparatus. The controller 30 may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a treatment recipe, for executing the process in each component according to various data and treatment conditions. Further, the user interface and the storage unit may be connected to the process controller. The treating recipe may be stored in a storage medium in the storage unit, and the storage medium may be a hard disk, and may also be a portable disk, such as a CD-ROM or a DVD, or a semiconductor memory, such as a flash memory.

The treating module 20 includes a buffer unit 200, a transfer chamber 300, a liquid treating chamber 400, and a drying chamber 500. The buffer unit 200 provides a space in which the substrate W loaded into the treating module 20 and the substrate W unloaded from the treating module 20 stay temporarily. The liquid treating chamber 400 performs a liquid processing process of treating the substrate W with a liquid by supplying a liquid onto the substrate W. The drying chamber 500 performs a drying process of removing the liquid residual on the substrate W. The transfer chamber 300 transfers the substrate W between the buffer unit 200, the liquid treating chamber 400, and the drying chamber 500.

A longitudinal direction of the transfer chamber 300 may be provided in the first direction X. The buffer unit 200 may be disposed between the index module 10 and the transfer chamber 300. The liquid treating chamber 400 and the drying chamber 500 may be disposed on the side portion of the transfer chamber 300. The liquid treating chamber 400 and the transfer chamber 300 may be disposed along the second direction Y. The drying chamber 500 and the transfer chamber 300 may be disposed along the second direction Y. The buffer unit 200 may be located at one end of the transfer chamber 300.

According to the example, the liquid treating chambers 400 are disposed on both sides of transfer chamber 300, and the drying chambers 500 are disposed on both sides of the transfer chamber 300, and the liquid treating chambers 400 may be disposed closer to the buffer unit 200 than the drying chambers 500. At one side of the transport chamber 300, the liquid treating chambers 400 may be provided in an arrangement of A×B (each of A and B is 1 or a natural larger than 1) in the first direction X and the third direction Z. Further, at one side of the transfer chamber 300, the drying chambers 500 may be provided in number of C×D (each of C and D is 1 or a natural number larger than 1) in the first direction 92 and the third direction 96. Unlike the above, only the liquid treating chambers 400 may be provided on one side of the transfer chamber 300, and only the drying chambers 500 may be provided on the other side of the transfer chamber 300.

The transfer chamber 300 includes a transfer robot 320. A guide rail 324 of which a longitudinal direction is provided in the first direction X is provided in the transfer chamber 300, and the transfer robot 320 may be provided to be movable on the guide rail 324. The index robot 320 includes a hand 322 on which the substrate W is placed, and the hand 322 may be provided to be movable forward and backward directions, rotatable about the third direction Z and movable along the third direction Z. The plurality of hands 322 is provided while being spaced apart from each other in the vertical direction, and is capable of independently moving forward and backward.

The buffer unit 200 includes a plurality of buffers 220 on which the substrate W is placed. The buffers 220 may be disposed to be spaced apart from each other along the third direction Z. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

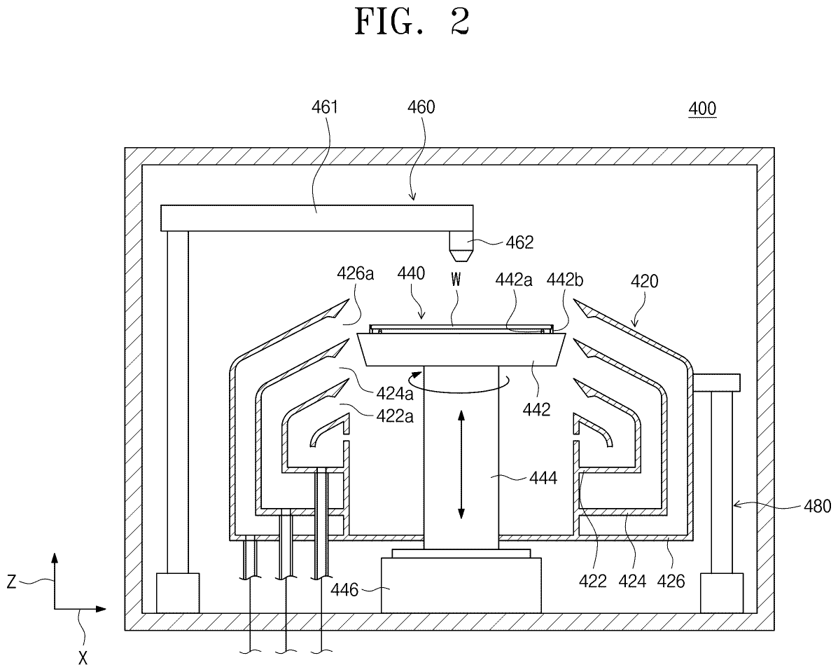

FIG. 2 is a diagram schematically illustrating a liquid treating chamber of FIG. 1 according to an exemplary embodiment.

Referring to FIG. 2, the liquid treating chamber 400 includes a housing 410, a cup 420, a support unit 440, a liquid supply unit 460, and a lifting unit 480.

The housing 410 may have an interior space where the substrate W is processed. The housing 410 may have a generally hexahedral shape. For example, the housing 410 may have a cuboidal shape. Additionally, the housing 410 may have an opening (not illustrated) through which the substrate W is loaded or unloaded. Additionally, the housing 410 may be equipped with a door (not illustrated) that selectively opens and closes the opening.

The cup 420 may have a barrel shape with an open top. The cup 420 has a processing space, and the substrate W may be liquid-treated within the processing space. The support unit 440 supports the substrate W in the processing space. The liquid supply unit 460 supplies the treatment solution onto the substrate W supported on the support unit 440. The treatment solution may be provided in a plurality of types and may be supplied sequentially onto the substrate W. The lifting unit 480 adjusts a relative height between the cup 420 and the support unit 440.

According to the example, the cup 420 includes a plurality of collection containers 422, 424, and 426. Each of the collection containers 422, 424, and 426 has a collection space of collecting the liquid used for the treating of the substrate. Each of the collection containers 422, 424, and 426 is provided in a ring shape surrounding the support unit 440. As the liquid processing process proceeds, the treatment solution scattered by the rotation of the substrate W enters the collection space through inlets 422a, 424a, and 426a of the respective collection containers 422, 424, and 426. According to the example, the cup 420 includes a first collection container 422, a second collection container 424, and a third collection container 426. The first collection container 422 is disposed to surround the support unit 440, the second collection container 424 is disposed to surround the first collection container 422, and the third collection container 426 is disposed to surround the second collection container 424. A second inlet 424a, which introduces the liquid into the second collection container 424, may be located above a first inlet 422a, which introduces the liquid into the first collection container 422, and a third inlet 426a, which introduces the liquid into the third collection container 426, may be located above the second inlet 424a.

The support unit 440 includes a support plate 442 and a driving shaft 444. An upper surface of the support plate 442 may be provided in a generally circular shape, and may have a diameter larger than a diameter of the substrate W. In the center portion of the support plate 442, a support pin 442a is provided to support the rear surface of the substrate W, and the support pin 442a is provided with its upper end protruding from the support plate 442 so that the substrate W is spaced apart from the support plate 442 by a certain distance. A chuck pin 442b is provided to an edge of the support plate 442. The chuck pin 442b is provided to protrude upward from the support plate 442, and supports the lateral portion of the substrate W so that the substrate W is not separated from the support unit 440 when the substrate W is rotated. The driving shaft 444 is driven by a driver 446, is connected to the center of the bottom surface of the substrate W, and rotates the support plate 442 with respect to the central axis thereof.

In one example, the liquid supply unit 460 may include a nozzle 462. The nozzle 462 may supply the treatment liquid to the substrate W. The treatment liquid may be a chemical, rinse solution, or organic solvent. The chemical may be a chemical having the nature of strong acid or strong base. In addition, the rinse solution may be pure. Furthermore, the organic solvent may be isopropyl alcohol (IPA). Additionally, the liquid supply unit 460 may include a plurality of nozzles 462, each of which may supply a different type of treatment liquid. For example, one of the nozzles 462 may supply a chemical, another of the nozzles 462 may supply a rinse solution, and yet another of the nozzles 462 may supply an organic solvent. Further, the controller 30 may control the liquid supply unit 460 to supply an organic solvent from another one of the nozzles 462 to the substrate W after supplying a rinse solution from the other one of the nozzles 462. Thus, the rinse liquid supplied to the substrate W may be replaced with an organic solvent having low surface tension.

The lifting unit 480 moves the cup 420 in the vertical direction. By the vertical movement of the cup 420, a relative height between the cup 420 and the substrate W is changed. Accordingly, since the collection containers 422, 424, and 426 for collecting the treatment liquid are changed according to the type of the liquid supplied to the substrate W, the liquids may be separated and collected. Unlike the description, the cup 420 may be fixedly installed, and the lifting unit 480 may move the support unit 440 in the vertical direction.

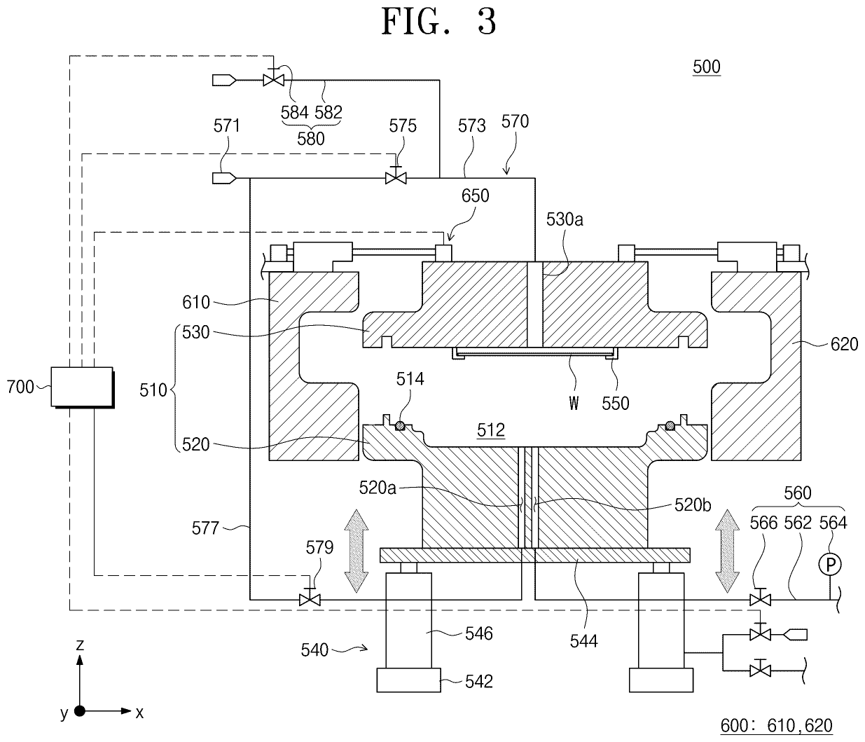

FIG. 3 is a diagram schematically illustrating the drying chamber of FIG. 1 according to an exemplary embodiment.

Referring to FIG. 3, the drying chamber 500 according to the exemplary embodiment of the present invention may remove any residual treatment liquid on the substrate W by using a drying fluid in a supercritical state. For example, the drying chamber 500 may perform a drying process to remove the organic solvent remaining on the substrate W by using carbon dioxide (CO2) in a supercritical state.

The drying chamber 500 includes a chamber body 510, a lifting member 540, a substrate support unit 550, an exhaust unit 560, a fluid supply unit 570, a clamping member 600, a moving member 650, and a controller 700.

The chamber body 510 has a processing space 512 inside which the substrate W is treated. The chamber body 510 seals the processing space 512 from the outside while treating the substrate W.

The chamber body 510 includes a first body 520, a second body 530, and a sealing member 514. The second body 530 is provided with a stepped bottom surface. The second body 530 is provided with a shape such that the center portion of the bottom surface is lower than the edge portion.

The first body 520 and the second body 530 are combined with each other to form the processing space 512.

The second body 530 is provided as an upper body positioned above the first body 520, and the first body 520 is provided as a lower body positioned below the second body 530.

Any one of the first body 520 and the second body 530 may be configured to be movable relative to the other. For example, the first body 520 may be disposed below the second body 530, the second body may be fixed in position, and the first body may be moved in an upward or downward direction by the lifting member 540 described later.

The sealing member 514 seals the gap between the first body 520 and the second body 530 to increase the airtightness of the processing space 512 when the first body 520 and the second body 530 are in the sealed position. The sealing member 514 is positioned between the first body 520 and the second body 530. The sealing member 514 has an annular ring shape. For example, the sealing member 514 may be provided as an O-ring. The sealing member 514 is provided on a top surface of the first body 520 or a bottom surface of the second body 530. In the present exemplary embodiment, the sealing member 514 is described as being provided on the top surface of the first body 520. On the top surface of the first body 520, a sealing recess is formed into which the sealing member 514 is inserted. A portion of the sealing member 514 is positioned to be inserted into the sealing recess, and another portion is positioned to protrude from the sealing recess. The sealing member 514 may be provided from a material having elasticity.

The first body 520 is provided with protrusions 522 on the surface that is in contact with the second body 530.

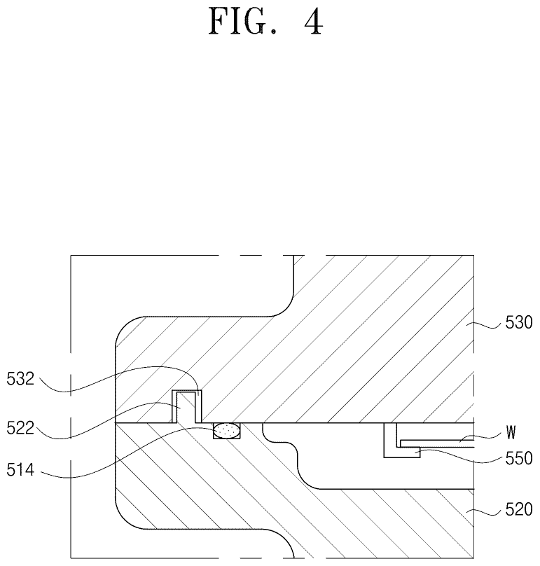

FIG. 4 is an enlarged view of a portion where the first body 520 and the second body 530 of FIG. 3 are in contact with each other. Referring to FIG. 4, the protrusion 522 is disposed further out than the sealing member 514 in a radial direction of the chamber body 510. When viewed from above, the protrusion 522 is provided in a ring shape. When the sealing member 514 is in an uncompressed state, the top end of the protrusion 522 is formed at a position higher than the top end of the sealing member 514.

The second body 530 is provided with a receiving portion 532. The receiving portion 532 is formed as a recess shaped to receive the protrusion 522, and the protrusion 522 is inserted into the receiving portion 532 when the first body 520 and the second body 530 are in the sealed position. The sides of the protrusion 522 and the receiving portion 532 are formed such that they do not contact each other when the first body 520 and the second body 530 are in the sealed or open position. That is, the protrusion 522 is formed so as not to be in contact with an inner wall of the second body 530 that provides the receiving portion 532.

The widths and heights of the protrusion and the receiving portion, or a correlation thereof, may be suitably selected based on the material of the chamber body, the distance to be spaced between the first body 520 and the second body 530 during the substrate treating process, the pressure of the fluid inside the processing space, and the like.

Referring again to FIG. 3, the lifting member 540 adjusts the relative position between the first body 520 and the second body 530. In one example, the lifting member 540 lifts the first body 520 in an upward or downward direction. The lifting member 540 lifts any one of the first body 520 and the second body 530 such that the chamber body 510 is moved to the open position or the sealed position. For example, the position of the second body 530 may be fixed, and the first body 520 may be lifted along the third direction Z by the lifting member 540. Here, the open position is a position in which the first body 520 and the second body 530 are spaced apart from each other, and the sealed position is a position in which the first body 520 and the second body 530 are in close contact with each other. The open position includes a position where the first body 520 and the second body 530 are spaced apart by a first separation distance D1 or a second separation distance D2, which will be described later.

The lifting member 540 includes a lifting driver 542, a lifting plate 544, and a lifting shaft 546. The lifting driver 542 is provided in plurality and is coupled to the lifting plate 544. The lift plate 544 is fixedly coupled to the first body 520. The lifting plate 544 is provided in the shape of a circular plate.

The lifting shaft 546 is fixedly coupled to the lifting plate 544. The lifting shafts 546 are provided in plurality. The lifting shafts 546 are positioned to be arranged along a circumferential direction. The lifting driver 542 lifts each of the lifting shafts 546. The lifting drivers 542 are provided in plurality and are coupled in one-to-one correspondence with the lifting shafts 546. When the lifting drivers 542 are provided with drive force to lift the lifting shafts 546 and lifting plates 574, the first body 520 is also lifted and moved with the lifting plates 574, and the first body 520 and second body 530 are moved to the sealed position where the processing space is sealed.

Each of the lift drivers 542 is provided with the same drive force and the drive force of each of the lift drivers 542 is equally released. Thus, the plurality of lifting shafts 546 is positioned at the same height during lifting, and the lifting plate 544 and the first body 520 may be lifted while remaining the horizontal state. For example, the lifting driver 542 may be a motor or cylinder, or an driver capable of multi-stage driving, but the present exemplary embodiment will be described using an example where the lifting driver 542 is a motor.

A heater for heating the drying fluid supplied to the processing space 512 may be buried in the chamber body 510. The heater may receive power from the outside to generate heat. The heater may be provided to each of the first body 520 and the second body 530, or may be provided to only one of the first body 520 or the second body 530.

The substrate support unit 550 supports the substrate W in the processing space 512.

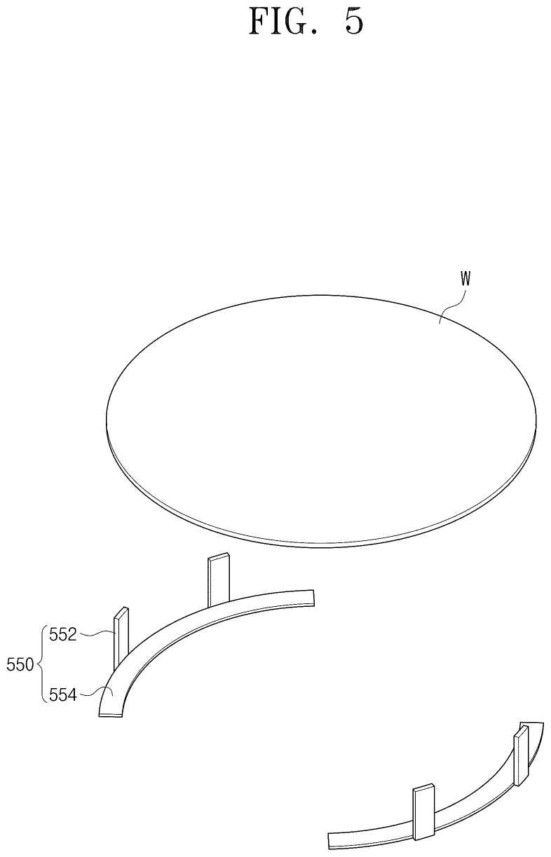

FIG. 5 is a perspective view of the substrate support unit of FIG. 3. Referring to FIG. 5, the substrate support unit 550 supports the substrate W with the treated face of the substrate W facing upward. The substrate support unit 455 includes supports 552 and substrate retainers 554. The support 552 is provided in the shape of a bar extending downwardly from a bottom surface of the first body 520. The supports 552 are provided in plurality. For example, the supports 552 can be four. The substrate retainer 554 supports a bottom edge region of the substrate W. The substrate retainers 554 may be provided in plurality, each supporting a different region of the substrate W. For example, the substrate retainers 554 may be two. When viewed from above, the substrate retainers 554 are provided in the shape of a rounded plate. When viewed from above, the substrate retainers 554 are positioned on the inner side of the support. Each of the substrate retainers 554 is provided to have a ring shape in combination with each other. Each of the substrate retainers 554 is spaced apart from each other.

Referring again to FIG. 3, the exhaust unit 560 exhausts the atmosphere of the processing space 512. Process byproducts generated in the processing space 512 are exhausted through the exhaust unit 560. The exhaust can be natural or forced exhaust. The exhaust unit 560 can also regulate the pressure in the processing space 512 while exhausting process byproducts. The exhaust unit 560 includes an exhaust line 562 and a pressure measurement member 564. The exhaust line 562 is connected to an exhaust port 520b formed in the first body 520. The exhaust line 562 may be connected to a depressurization member (not shown) that provides decompression to the processing space. The decompressing member may be a pump. However, without limitation, the decompressing member may be any known device capable of providing decompression to the processing space.

An exhaust valve 566 installed in the exhaust line 562 is adjustable to regulate the exhaust volume of the processing space 512. The pressure measuring member 564 is installed in the exhaust line 562 and measures the pressure in the exhaust line 562. The pressure measuring member 564 is positioned upstream of the exhaust valve 566 with respect to the exhaust direction. By the exhaust unit 560, the processing space 512 may be decompressed to normal pressure or to a pressure corresponding to the outside of the chamber body 510. The fluid supply unit 570 supplies the processing fluid to the processing space 512. The processing fluid supplied by the fluid supply unit 570 may include carbon dioxide (CO2). The processing fluid is supplied in a supercritical state by a critical temperature and critical pressure.

The fluid supply unit 570 can include a fluid supply source 571, a first supply line 573, a first supply valve 575, a second supply line 577, and a second supply valve 579.

The fluid supply source 571 stores and/or supplies the processing fluid that is supplied to processing space 512. The fluid supply source 571 supplies the treatment fluid to the first supply line 573 and/or the second supply line 577. The fluid supply source 571 may be provided in plurality, and the fluid supply source 571 corresponding to the treatment fluid being treated in the processing space 512 supplies the treatment fluid to the first supply line 573 and/or the second supply line 577. That is, the treatment fluid supplied from each of the first supply line 573 and the second supply line 577 may be the same type of fluid.

The first supply line 573 is connected to a first supply port 530a formed in the second body 530. The treatment fluid is supplied to the processing space 512 via the first supply line 573 and the first supply port 530a in sequence.

The second supply line 577 is connected with a second supply port 520a formed in the first body 520. The processing fluid is supplied to the processing space 512 via the second supply line 577 and the second supply port 520a sequentially.

The first supply valve 575 is installed in the first supply line 573 and the second supply valve 579 is installed in the second supply line 577. The first supply valve 575 and the second supply valve 579 may be on/off valves. Depending on the on/off of the first supply valve 575 and the second supply valve 579, the first supply line 573 and the second supply line 577 may be selectively opened and closed, and the treatment fluid may selectively flow in the first supply line 573 or the second supply line 577.

The example described above illustrates, but is not limited to, that the first supply line 573 and the second supply line 577 are connected to one fluid supply source 571 among the plurality of fluid supply sources 571. The first supply line 573 may be connected to any one of the plurality of fluid supply sources 571, and the second supply line 577 may be connected to a different one of the fluid supply sources 571.

In one example, the treatment fluid may be supplied from the second supply port 520a, which is opposite the non-treated face of the substrate W, and then treatment fluid may be supplied from the first supply port 530a, which is opposite the treated face of the substrate W. Thus, the treatment fluid may first be supplied to the processing space 512 via the second supply line 577 and then supplied to the processing space 512 via the first supply line 573. This prevents the initially supplied treatment fluid from being supplied to the substrate W while the treatment fluid is below a critical pressure or critical temperature.

The gas supply unit 580 supplies purge gas to the processing space 512. The gas supply unit 580 supplies purge gas until the processing space 512 reaches a preset pressure. The preset pressure is a pressure that is higher than the external pressure of the chamber body 510. In one example, the preset pressure may be 10 Bar. The gas supply unit 580 includes a purge gas line 582. The purge gas line 582 is connected to the first supply line 573. The purge gas line 582 supplies the treatment fluid to the first supply line 573. A gas valve 584 is installed in the purge gas line 582. The gas valve 584 opens and closes the purge gas line 582. For example, the purge gas may be inert gas. The purge gas may be nitrogen gas (N2).

The clamping member 600 clamps the chamber body 510, that is, the first body 520 and the second body 530, located at the sealed position. This prevents a gap from developing between the first body 520 and the second body 530, even if the pressure in the processing space increases during the process.

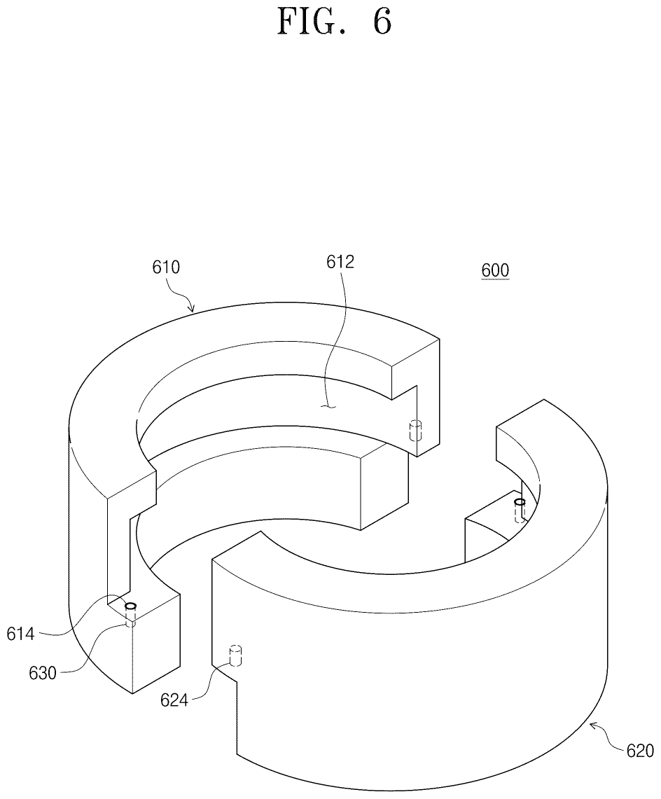

FIG. 6 is a perspective view of the clamping member of FIG. 3. Referring to FIG. 6, the clamping member 600 includes a first clamp 610, a second clamp 620, and a locking pin 630. The first clamp 610 and the second clamp 620 are located on side portions of the chamber body 510. In one example, each of the first clamp 610 and the second clamp 620 is positioned to face each other with the chamber body 510 interposed therebetween.

The first clamp 610 and the second clamp 620 can clamp the chamber body 510 in opposite positions. Each of the first clamp 610 and the second clamp 620 is provided in a shape that surrounds the chamber body 510. Each of the first clamp 610 and the second clamp 620 has a clamp recess 612 formed on an inner surface facing the chamber body 510. The inner surface of the first clamp 610 and the second clamp 620 may have a shape substantially corresponding to an outer surface of the chamber body 510 located at the sealed position. In the clamp recess 612, an edge portion of the first body 520 and an edge portion of the second body 530 in the sealed position are insertable. That is, each of the edge portion of the first body 520 and the edge portion of the second body 530 is provided as a region to be clamped.

The clamping member 600 is movable to a lock position or a release position. The lock position is defined herein as a position in which the first clamp 610 and the second clamp 620 are close together to clamp the first body 520 and the second body 530, and the release position is defined as a position in which the first clamp 610 and the second clamp 620 are spaced apart from the first body 520 and the second body 530.

The first clamp 610 and the second clamp 620 are provided to have an annular ring shape in combination with each other in the lock position. For example, a vertical section of any one of the first clamp 610 and the second clamp 620 may be provided to have a “C” or “D” shape, and a vertical section of the other may be provided to be symmetrical to the vertical section of the one with respect to a vertical axis.

The first clamp 610 is provided to have one side that is in contact with the second clamp 620 to be stepped. The second clamp 620 is provided to have the other side that is in contact with the first clamp 610 to be stepped.

The first side of the first clamp 610 and the other side of the second clamp 620 are provided in a staggered shape. In one example, an upper end of the one side of the first clamp 610 may be provided to be stepped longer than a lower end of the one side of the first clamp 610, and an upper end of the other side of the second clamp 620 may be provided to be stepped longer than a lower end of the other side of the second clamp 620. A first pin recess 614 is formed in the stepped region of the first clamp 610 in which the locking pin 630 is located, and a second pin recess 624 is formed in the stepped region of the second clamp 620. Each of the first pin recess 614 and the second pin recess 624 is provided to face in a direction perpendicular to the direction of movement of the clamping member 600. In the lock position, the first pin recess 614 and the second pin recess 624 are positioned opposite each other. In one example, at the lock position, the locking pin 630 may protrude from the first pin recess 614 and be inserted into the second pin recess 624. Further, the first pin recess 614 may be further formed in the second clamp 620, and the second pin groove 624 may be further formed in the first clamp 610.

Referring again to FIG. 3, the moving member 650 moves the clamping member 600 to the lock position and the release position.

The first clamp 610 and the second clamp 620 may be moved by the moving member 650. The moving members 650 may be provided in plurality. Any one of the moving members 650 may be connected with the first body 520 and the first clamp 610, and another of the moving members 650 may be connected with the first body 520 and the second clamp 620.

The controller 700 controls the lifting member 540 and the moving member 650. The controller 700 controls the lifting member 540 to move the chamber body 510 to the sealed position or the open position, and controls the moving member 650 to move the clamping member 600 to the lock position or the release position.

The controller 700 may also control the fluid supply unit 570 such that the pressure in the processing space 512 is greater than the pressure applied to the first body 520 in the sealed position. Further, the controller 700 can control the opening and closing of each of the valves 566, 575, 579, and 584 to supply or stop supplying fluid.

In one example, when the chamber body 510 is moved from the open position to the sealed position, the clamping member 600 may be moved from the release position to the lock position. The controller 700 may adjust the lifting speed of the first body 520.

The following describes a method of processing a substrate by using the drying chamber 500 described above.

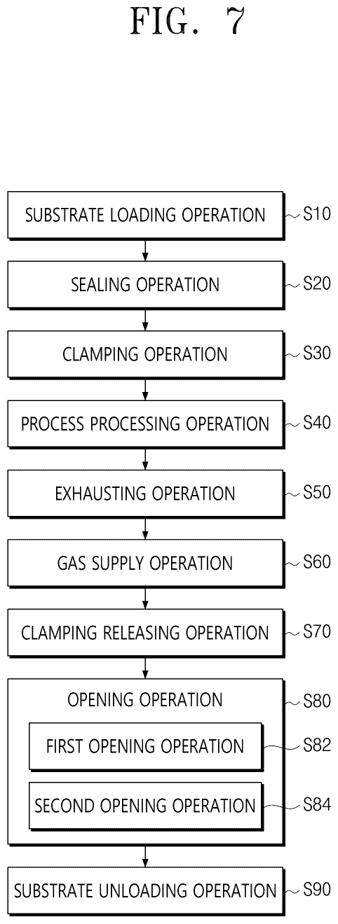

FIG. 7 is a flowchart illustrating a process of processing a substrate by using the apparatus of FIG. 3.

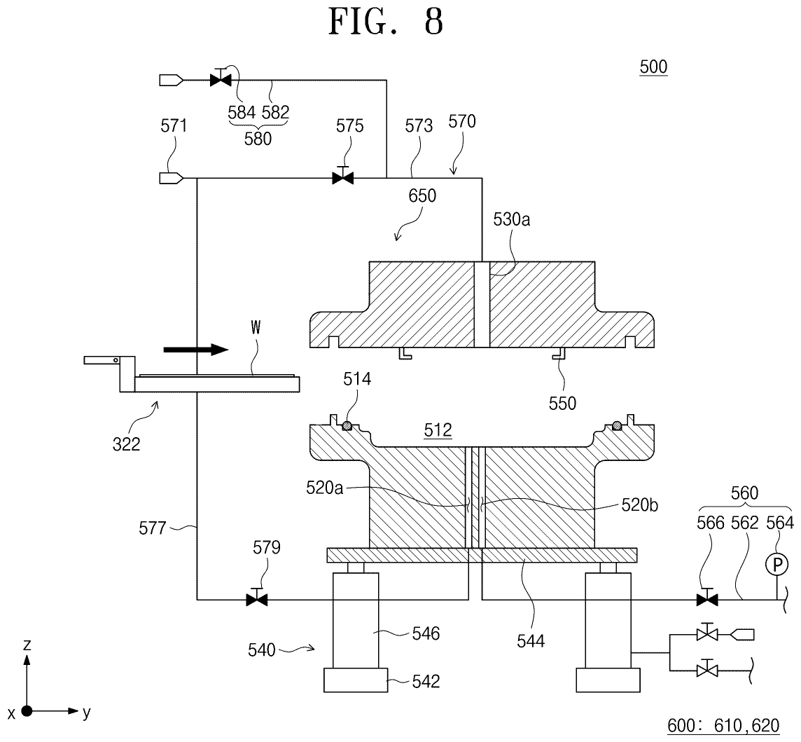

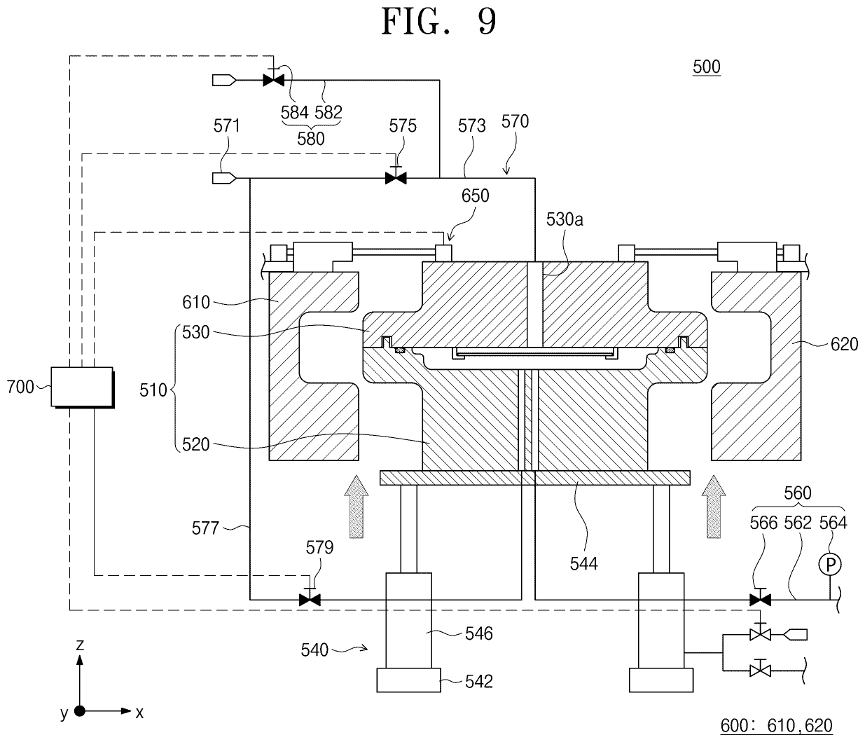

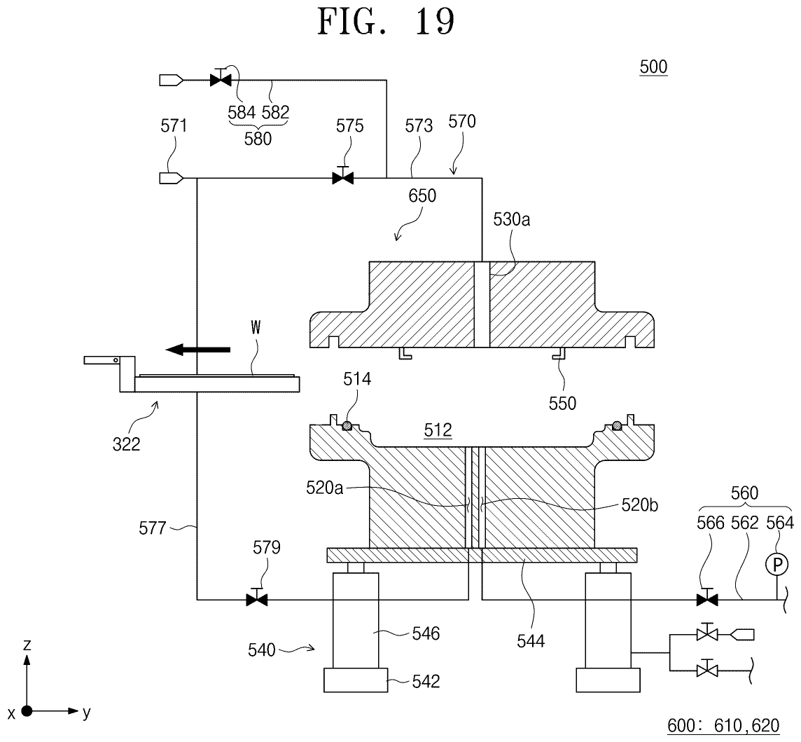

FIGS. 8 to 19 are drawings illustrating the process of processing a substrate according to each operation of the flowchart of FIG. 9 by using the apparatus of FIG. 3. In the drawings, a valve with a white interior is a valve in the open state and a valve with a black interior is a valve in the closed state.

The controller 700 may control the lifting driver 542 and the moving member 650, and may control the valves 566, 575, 579, and 584 installed in the fluid supply unit 570, the gas supply unit 580, and the exhaust line 562, respectively, to perform the process of sequentially treating the substrate as described below.

Referring now to FIGS. 8 to 19, a method for processing a substrate W includes a substrate loading operation S10, a sealing operation S20, a clamping operation S30, a process processing operation S40, an exhaust operation S50, a gas supply operation S60, a clamping releasing operation S70, an opening operation S80, and a substrate unloading operation S90.

FIG. 8 is a diagram illustrating a simplified view of the drying chamber 500 when the substrate loading operation is in progress. In the substrate loading operation S10, the substrate is loaded into the processing space. The substrate W is loaded into the processing space 512 along the second direction Y while being placed on the hand 322 of the transfer robot 320. The substrate W is supported by the substrate support unit 550.

The chamber body 510 is in an open state, where the gap between the first body 520 and the second body 530 is a second separation distance D2, which is the same as the substrate unloading operation S90 described later. The gap between the first body 520 and the second body 530 will be described later.

In this operation, the clamping members 600 are in positions in which the first clamp 610 and the second clamp 620 are spaced apart from the first body 520 and the second body 530. That is, the clamping members 600 are in the release position.

In this operation, the valves 566, 575, 579, and 584 installed in the fluid supply unit 570, the gas supply unit 580, and the exhaust line 562, respectively, are in the closed state.

The sealing operation S20 is carried out after the substrate loading operation S10.

FIG. 9 is a diagram briefly illustrating the drying chamber 500 when the sealing operation S20 is in progress. In the sealing operation S20, the first body 520 is raised by the lifting driver 542, and the first body 520 and the second body 530 are in close contact with each other. That is, the first body 520 and the second body 530 are in the sealed position.

The processing space 512 is sealed by the first body 520 and the second body 530.

After the sealing operation S20, the clamping operation S30 is performed.

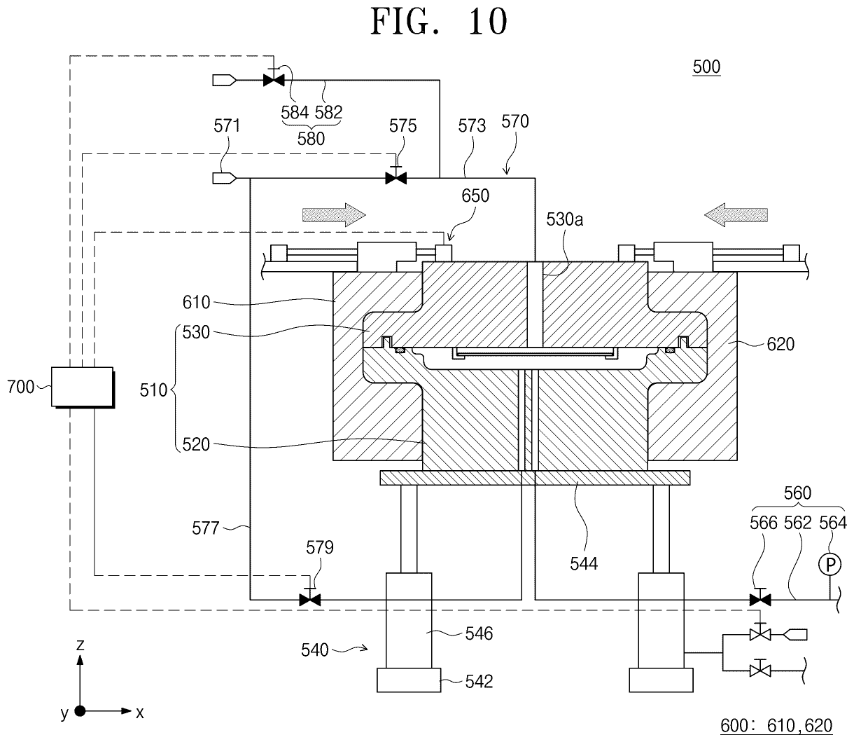

FIG. 10 is a diagram briefly illustrating the drying chamber 500 when the clamping operation S30 is performed. In the clamping operation S30, to limit the movement of the first body 520 and the second body 530 when the high pressure drying process is performed, the first clamp 610 and the second clamp 620 are moved from the release position to the locked position to clamp the first body 520 and the second body 530.

After the clamping operation S30, the process processing operation S40 is performed.

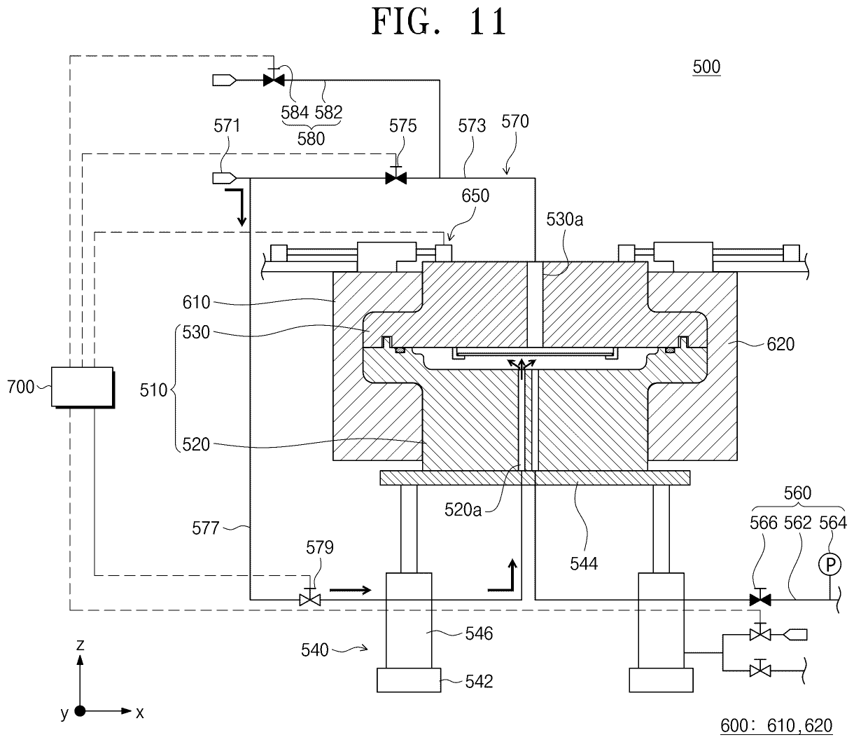

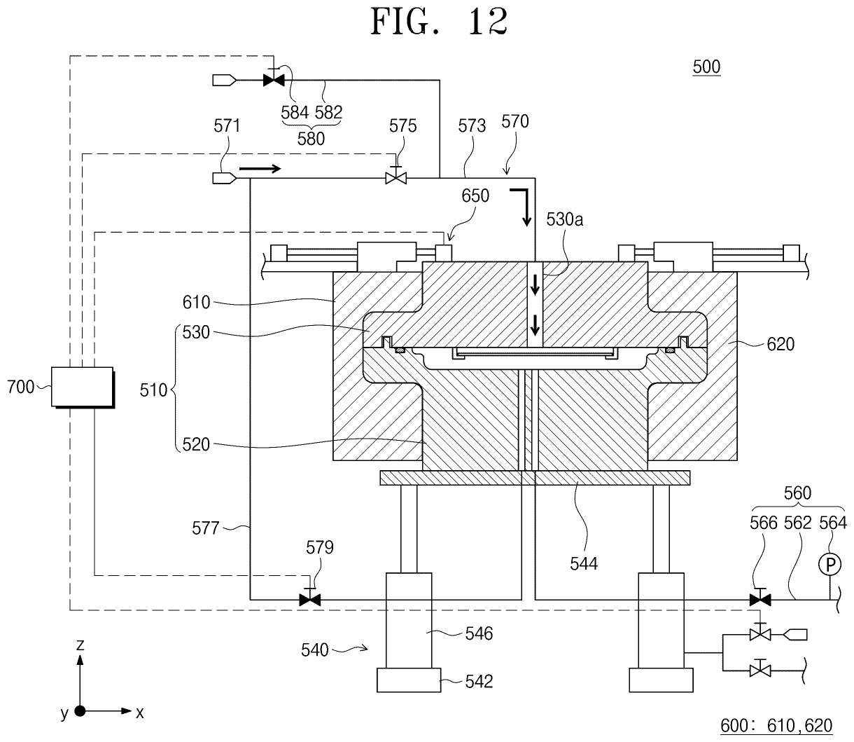

FIGS. 11 and 12 briefly illustrate the drying chamber during the process processing operation.

As described above, when the processing fluid is supplied from the second supply port 520a facing the non-treated face of the substrate W, and the processing space 512 reaches a critical temperature and a critical pressure, the fluid supply from the second supply port 520a is stopped and the fluid supply is started through the first supply port 530a facing the treated face of the substrate W.

At this stage, it is illustrated that the exhaust valve 566 installed in the exhaust line 562 is in a closed state. However, in the process processing operation, the supply and exhaust of the treatment fluid may be performed sequentially or simultaneously, and the opening and closing of the exhaust valve 566 and the first supply valve 575 may be controlled accordingly.

The treatment fluid that has reached the critical pressure or critical temperature is supplied to the substrate W to treat the substrate, and when the process processing operation S40 is complete, the exhaust operation S50 proceeds.

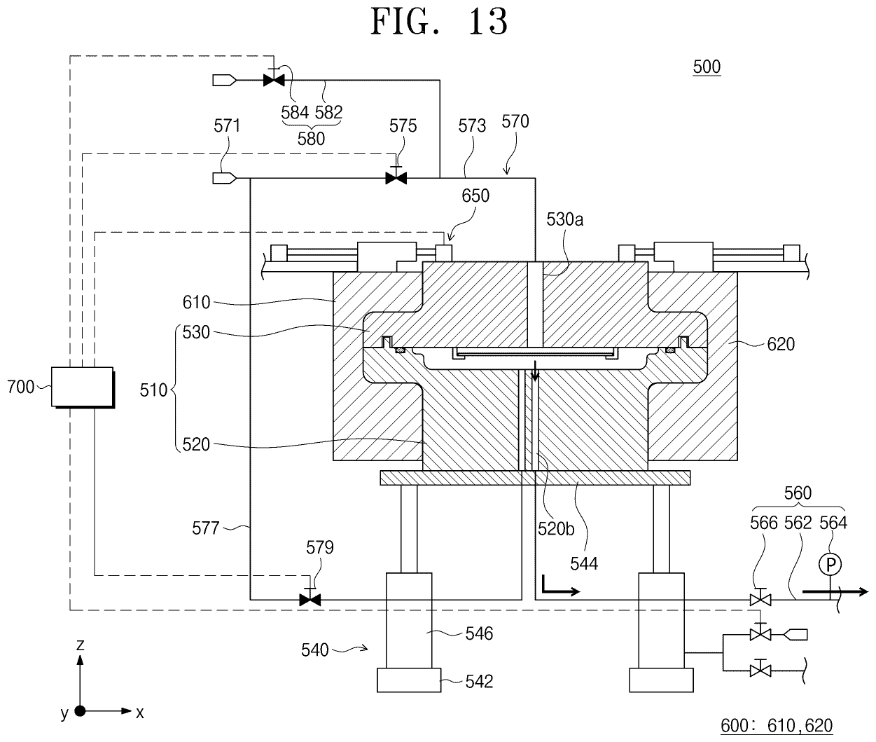

FIG. 13 briefly illustrates the drying chamber during the exhaust operation.

The exhaust operation S50 involves exhausting residual fluid from the processing space 512. During the exhaust operation S50, the atmosphere in the processing space 512 is exhausted through the exhaust unit 560. The exhaust operation S50 includes exhausting the atmosphere of the processing space 512 until the processing space 512 reaches an exhaust pressure. The exhaust pressure can be a pressure that corresponds to normal pressure and the outside of the chamber body 510.

Upon completion of the exhaust operation S50, the exhaust through the exhaust unit 560 stops, and the exhaust valve 566 is closed to proceed with the gas supply operation S60.

The time point at which the gas supply operation S60 is performed after completion of the exhaust operation S50 may be determined by the pressure in the exhaust line 562 measured by the pressure measuring member 564 installed in the exhaust line 562. For example, the exhaust valve 566 may be closed when the pressure in the exhaust line 562 measured by the pressure measuring member 564 is 0 bar, that is, when it is determined that there is no treatment fluid being exhausted through the exhaust line 562.

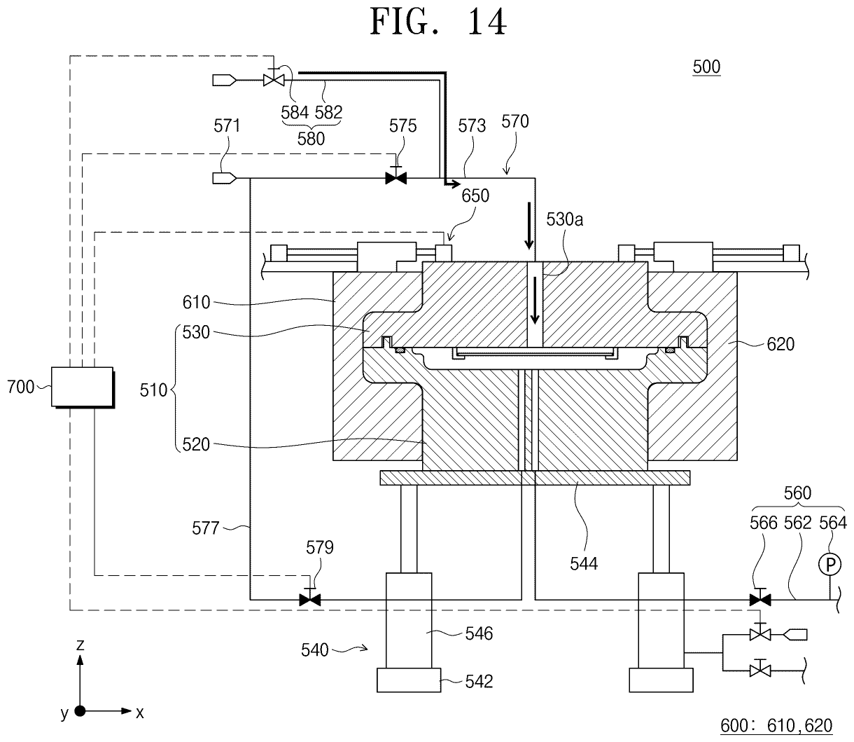

The gas supply operation S60 includes supplying purge gas to the processing space 512. In the gas supply operation S30, the purge gas is supplied until the processing space 512 reaches a preset pressure. As illustrated in FIG. 14, during the supply of the gas, the exhaust valve 566 is the closed state, so that exhaust through the exhaust unit 560 stops. Here, the preset pressure is a pressure that is higher than the external pressure of the chamber body 510. In one example, the preset pressure may be 10 Bar.

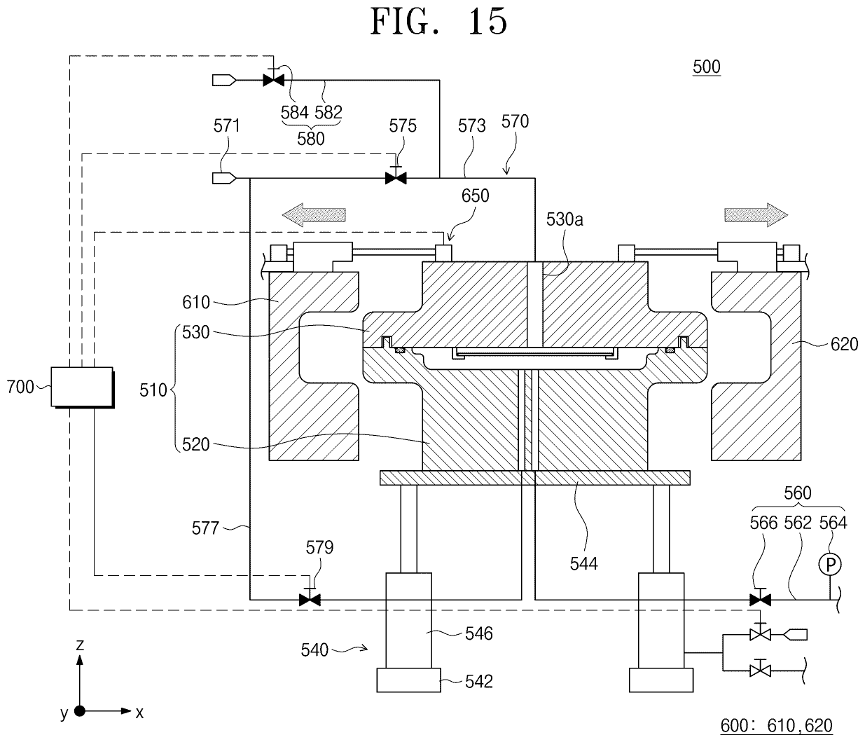

When the gas supply operation S60 is completed, the clamping releasing operation S70 is subsequently performed. FIG. 15 is a diagram briefly illustrating the drying chamber 500 when the clamping releasing operation is performed.

In the clamping releasing operation S70, the first clamp 610 and the second clamp 620 are moved from the lock position to the release position, and the clamping of the chamber body 510 is released, to allow the first body 520 and the second body 530 to move relative to each other in the subsequent opening operation S80. When the clamping is released, the opening operation S80 is performed.

The opening operation S80 includes a first opening operation S82 and a second opening operation S84. Each operation is performed sequentially.

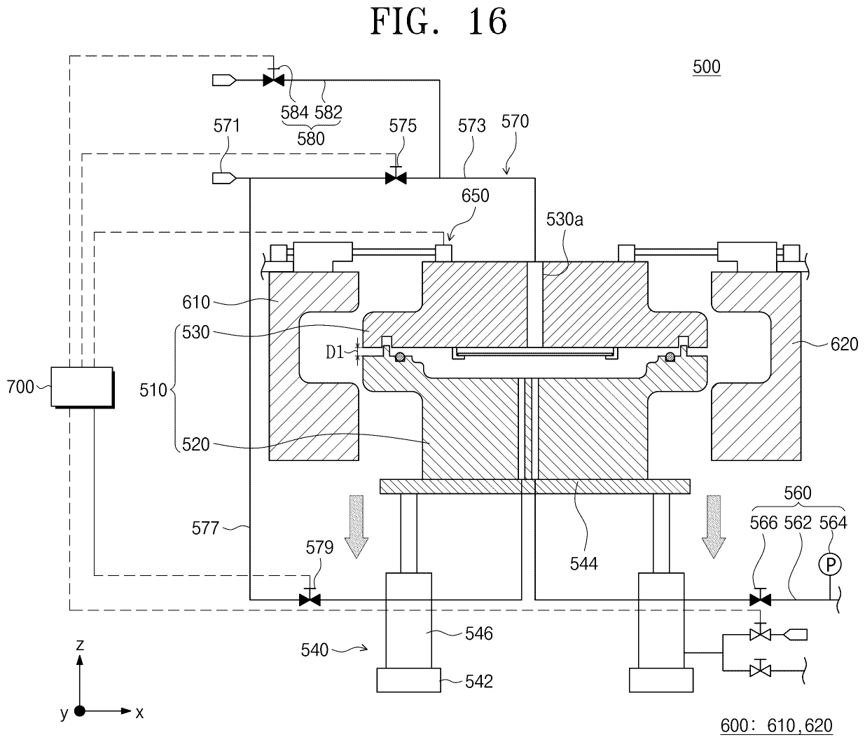

Referring to FIG. 16, in the first opening operation S82, the first body 520 and the second body 530 are moved relative to each other to be separated by a first separation distance D1.

As the processing space 512 is opened by the first separation distance D1, the atmosphere in the processing space 512 is discharged to the outside due to the pressure difference between the processing space 512 and the outside of the processing space 512. The atmosphere of the processing space 512 may include purge gas and residual treatment fluid.

In this case, the first separation distance D1 is shorter than the height by which the protrusion 522 formed on the first body 520 protrudes from the first body 520.

The first separation distance D1 is a distance that is thinner than the thickness of the hand 322 of the transfer robot 320.

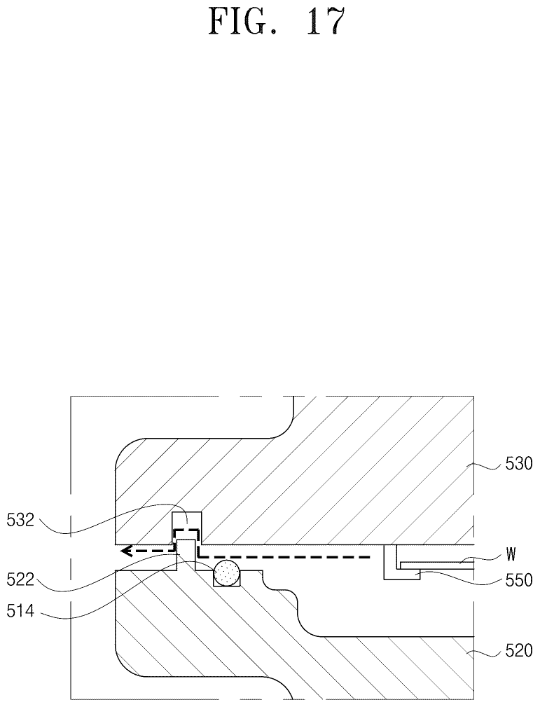

Thus, as shown in FIG. 17, the protrusion 522 is positioned on a straight path through which the atmosphere of the processing space 512 is discharged to the outside of the chamber body 510, and the atmosphere of the processing space 512 is slowly discharged through the space between the protrusion 522 and the receiving portion 532.

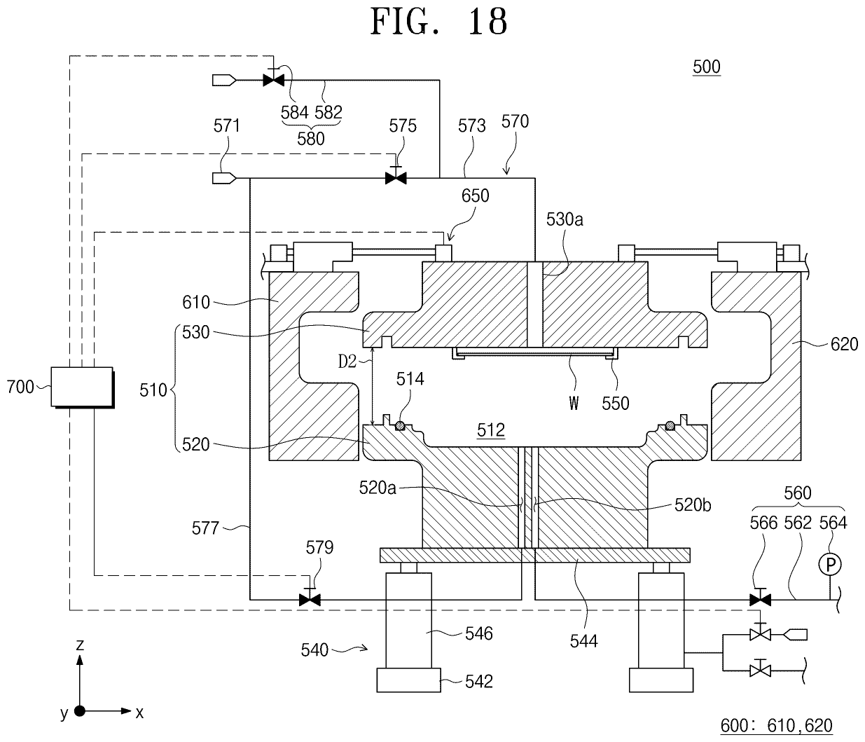

After the first opening operation S82, the second opening operation S84 is performed. In the second opening operation S84, the first body 520 and the second body 530 are moved relative to each other such that they are separated by a second separation distance D2. This process is illustrated in FIG. 18.

The second separation distance D2 is a distance that is spaced between the first body and the second body when the substrate W is loaded into the processing space 512 or when the substrate W is unloaded from the processing space 512. The second separation distance D2 is greater than the first separation distance D1.

When the first body 520 and the second body 530 move in relative to each other so that the gap between the first body 520 and the second body 530 in the second opening operation S84 becomes the second separation distance D2, the second opening operation S84 ends and the substrate unloading operation S90 is performed.

In the substrate unloading operation S90, the substrate is unloaded from the processing space 512. The substrate W is unloaded from the processing space 512 along the second direction Y in the state where the substrate is placed on the hand 322 of the transfer robot 320.

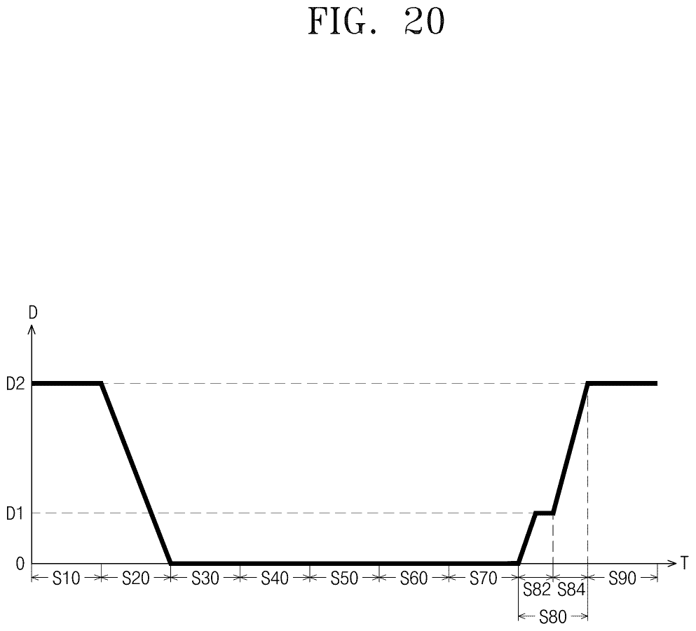

FIG. 20 is a graph plotting the gap, that is, the separation distance, between the first body 520 and the second body 530 according to each operation of the flowchart of FIG. 7.

According to the graph of FIG. 20, in the substrate loading operation S10, the gap between the first body 520 and the second body 530 is the second separation distance D2, and in the sealing operation S20, the chamber body 510 is moved to the sealed position and the processing space 512 is sealed, so the separation distance becomes zero. The chamber body 510 is then in the sealed position until the end of the clamping releasing operation S70, so that the gap between the first body 520 and the second body 530 is zero.

Then, when the first opening operation S82 proceeds, the lifting driver 542 of the lifting member 540 lowers the first body 520, and the gap between the first body 520 and the second body 530 increases to the first separation distance D1.

In the first opening operation S82, relative movement between the first body 520 and the second body 530 is stopped for a predetermined period of time to assist in the slow discharge of the atmosphere in the processing space 512. That is, the first opening operation S82 includes a period of time in which the first opening operation S82 stops in the state where the separation distance is the first separation distance D1 and the atmosphere of the processing space 512 is slowly discharged.

In a second opening operation S84, the lifting driver 542 of the lifting member 540 further lowers the first body 520, and the gap between the first body 520 and the second body 530 increases to the second separation distance D2.

The gap between the first body 520 and the second body 530 in the substrate unloading operation S90 is the second separation distance D2 as in the substrate loading operation S10.

As described above, in the exemplary embodiment of the present invention, prior to opening the processing space 512, purge gas is supplied to the processing space 512 to maintain the processing space 512 at a preset pressure above normal pressure. This can minimize the introduction of outside particles and outside airflow during the process of opening the processing space 512.

Furthermore, when the chamber body 510 is opened, the chamber body 510 is preferentially opened by the first separation distance D1, and then sequentially opened further by the second separation distance D2.

Thus, the atmosphere of the processing space 512 can be slowly discharged through the space between the protrusion 522 and the receiving portion 532.

Accordingly, the processing space 512 can be prevented from rapidly expanding, and the processing space 512 can be prevented from temporarily generating negative pressure.

In addition, the atmosphere in the processing space 512 has the effect of preventing outside particles and outside airflow from entering the processing space 512 by the pressure of the flow discharged to the outside of the processing space 512.

In the exemplary embodiment illustrated in FIG. 20 above, the rate at which the gap between the first body 520 and the second body 530 increases in the first opening operation S82 and the second opening operation S84 is shown to be the same, but is not limited thereto. To assist in slowly discharging the atmosphere in the processing space 512 when the gap between the first body 520 and the second body 530 becomes the first separation distance D1 according to the first opening operation S82, the speed at which the first body 520 and the second body 530 move relative to each other in the second opening operation S84, that is, the speed at which the gap between the first body 520 and the second body 530 increases, may be a lower speed than the speed at which the first body 520 and the second body 530 move relative to each other in the first opening operation S82.

In the exemplary embodiment illustrated in FIG. 20 above, the relative movement between the first body 520 and the second body 530 in the first opening operation S82 is shown to stop for a predetermined period of time, but is not limited thereto. It is also possible to perform the second opening operation S84 immediately without stopping the relative movement between the first body 520 and the second body 530 at a time when the gap between the first body 520 and the second body 530 becomes the first separation distance D1 according to the first opening operation S82.

In the exemplary embodiment described above, the purge gas line 582 is shown to be connected to the first supply line 573, but is not limited thereto. The purge gas line 582 may be configured to be connected to the second supply line 577, or may be configured to be connected to each of the first supply line 573 and the second supply line 577.

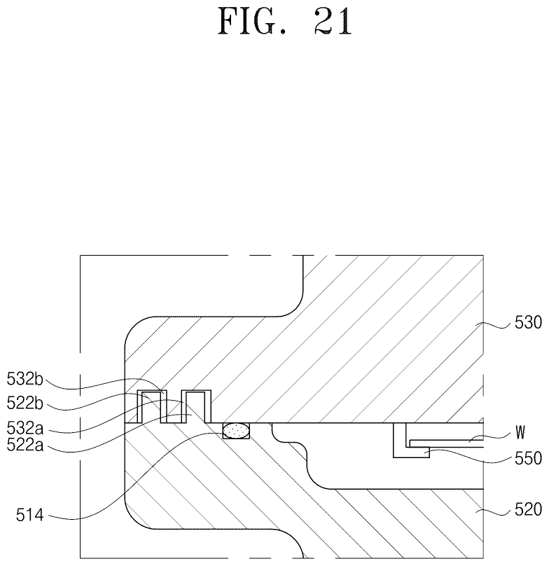

FIGS. 21 to 23 are diagrams illustrating a chamber body of the present invention according to modified exemplary embodiments. Configurations of the chamber body 510 illustrated in FIG. 3 will be designated with the same symbols as configurations of the chamber body 510 shown in FIG. 3, so that the detailed description thereof will be omitted, and modified exemplary embodiments will be described below with emphasis on configurations that differ from the present exemplary embodiment.

According to the modified example of FIG. 21, the first body 520 is provided with a plurality of protrusions 522a and 522b on a face that is in contact with the second body 530.

The plurality of protrusions 522a and 522b are disposed sequentially outside the sealing member 514 in a radial direction of the chamber body 510.

The second body 530 is provided with a plurality of receiving portions 532a and 532b corresponding to the plurality of protrusions 522a and 522b. While only two protrusions 522a and 522b and two receiving portions 532a and 532b are shown in FIG. 16, the protrusions and the receiving portions may be implemented with three or more.

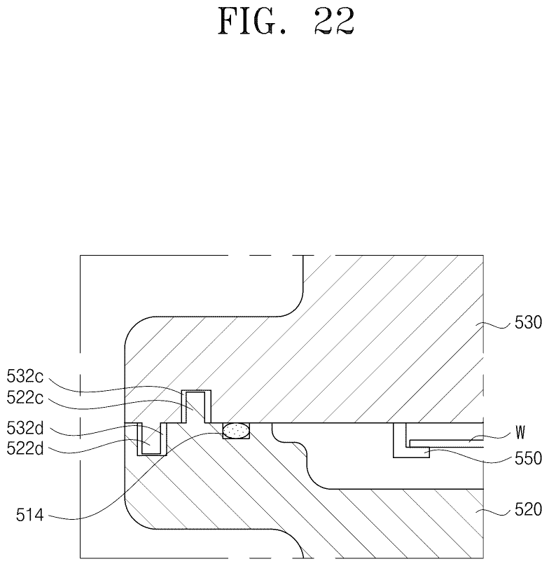

In the modified example shown in FIG. 22, the first body 520 is provided with the first protrusion 522c on a face that is in contact with the second body 530, and the second body 530 is provided with the second protrusion 522d on a face that is in contact with the first body 520. Further, the second body 530 is provided with the first receiving portion 532c and the first body 520 is provided with the second receiving portion 532d. The first receiving portion 532c is formed with a recess shaped to receive the first protrusion 522c, and the second receiving portion 532d is formed with a recess shaped to receive the second protrusion 522d. While the modified example according to FIG. 22 illustrates that the first body 520 and the second body 530 each provides one protrusion and one receiving portion, the first body 520 and the second body 530 may each provide one or more protrusions and receiving portions.

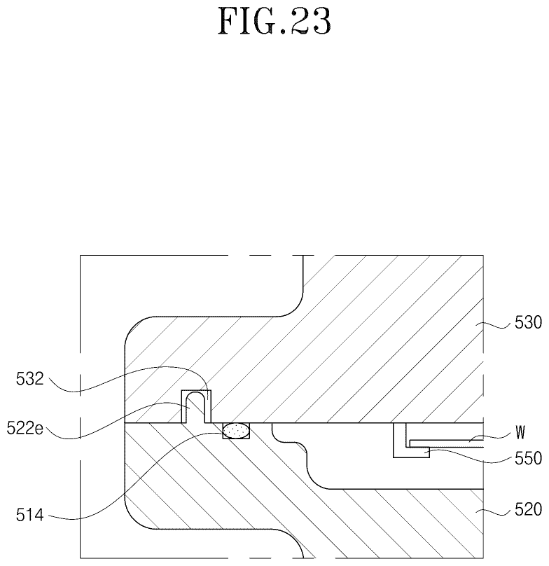

The protrusion 522e according to FIG. 23 has a hemispherical shape on its upper surface. As a result of this shape of the protrusions 522e, when the atmosphere of the processing space 512 is discharged to the outside of the chamber body 510, even though the protrusion 522e is present in the discharge path, the atmosphere of the processing space 512 may be discharged smoothly without forming turbulence. In the modified examples of FIGS. 21 to 23 above, the atmosphere in the processing space 512 can be slowly discharged through the space between the protrusion 522 and the receiving portion 532. The protrusions or receiving portions may be arranged or implemented in various shapes other than those shown in the exemplary embodiments above.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even if not specifically illustrated or described. The modifications are not to be considered as departing from the spirit and scope of the present invention, and all such modifications that would be obvious to one of ordinary skill in the art are intended to be included within the scope of the accompanying claims.

1. An apparatus for processing a substrate, the apparatus comprising:
a chamber including a first body and a second body which are combined with each other to form a processing space in which a processing process for a substrate is performed therein;
a driver for moving any one of the first body or the second body relative to the other such that a relative position between the first body and the second body is changeable between a sealed position at which the processing space is sealed from the outside and an open position at which the processing space is opened;
a support unit for supporting a substrate in the processing space; and
a fluid supply unit for supplying a processing fluid to the processing space; and
an exhaust unit for exhausting a fluid from the processing space,
wherein the first body is formed with a first protrusion on a face that is in contact with the second body,
the second body is formed with a first receiving portion, and
the first protrusion is provided to be inserted into the first receiving portion when the first body and the second body are at the sealed position.

2. The apparatus of claim 1, wherein the first protrusion and the first receiving portion are formed such that the first protrusion does not contact an inner wall providing the first receiving portion when the first body and the second body are at the sealed position or the open position.

3. The apparatus of claim 1, wherein the first protrusions are formed in plurality along a radial direction of the chamber.

4. The apparatus of claim 1, wherein the first protrusion is provided in a ring shape when viewed from above.

5. The apparatus of claim 1, wherein the chamber further includes a sealing member, and
The first protrusion is located further out than the sealing member in a radial direction of the chamber.

6. The apparatus of claim 5, wherein the first body is positioned below the second body, and
an upper end of the first protrusion is formed at a position higher than an upper end of the sealing member.

7. The apparatus of claim 1, wherein the second body is formed with a second protrusion on a face that is in contact with the first body,
the first body is formed with a second receiving portion, and
the second protrusion is provided to be inserted into the second receiving portion when the first body and the second body are at the sealed position.

8. The apparatus of claim 1, further comprising:
a clamping member for clamping the chamber when the first body and the second body are at the sealed position.

9. The apparatus of claim 1, further comprising:
a controller,
wherein the controller processes the substrate by supplying a first processing gas into the processing space in the state where the processing space is sealed,
subsequently, when the processing process for the substrate is completed, supplies a purge gas to the processing space until the processing space is at a preset pressure, and
subsequently, controls the driver to move the first body and the second body relative to each other such that the first body and the second body are spaced apart by a first separation distance, and
subsequently, moves the first body and the second body relative to each other such that the first body and the second body are separated by a second separation distance,
the first separation distance is a shorter than the second separation distance, and
the second separation distance is a distance that is separated between the first body and the second body when the substrate is loaded into the processing space or unloaded from the processing space.

10. The apparatus of claim 9, wherein the first separation distance is shorter than a height by which the first protrusion protrudes from the first body.

11.-17. (canceled)

18. An apparatus for processing a substrate, the apparatus comprising:
a chamber including a first body and a second body which are combined with each other to form a processing space in which a processing process for a substrate is performed therein;
a driver for moving any one the first body or the second body relative to the other such that a relative position between the first body and the second body is changeable between a sealed position at which the processing space is sealed from the outside and an open position at which the processing space is opened;
a support unit for supporting a substrate in the processing space; and
a fluid supply unit for supplying a processing fluid to the processing space;
an exhaust unit for exhausting a fluid from the processing space;
a clamping member for clamping the chamber when the first body and the second body are at the sealed position; and
a controller,
wherein the first body is formed with a protrusion on a face that is in contact with the second body,
the second body is formed with a receiving portion, and
the protrusion is provided to be inserted into the receiving portion when the first body and the second body are at the sealed position,
the controller clamps the chamber in the state where the processing space is sealed, supplies first processing gas to the processing space, supplies purge gas to the processing space until the processing space is at a preset pressure when the processing process for the substrate is completed, and releases the clamping, and controls the driver to move the first body and the second body relative to each other such that the first body and the second body are spaced apart by a first separation distance, and
the first separation distance is a shorter than a second separation distance, and
the second separation distance is a distance separated between the first body and the second body when the substrate is loaded into the processing space or unloaded from the processing space, and
the first separation distance is shorter than a height by which the protrusion protrudes from the first body.

19. The apparatus of claim 18, wherein the controller controls the driver to move the first body and the second body relative to each other such that the first body and the second body are spaced apart by a first separation distance, and
then stops the relative movement of the first body and the second body for a predetermined period of time before moving the first body and the second body relative to each other such that the first body and the second body are spaced apart by the second separation distance.

20. The apparatus of claim 18, wherein the chamber further includes a sealing member, and
the protrusion is located further out than the sealing member in a radial direction of the chamber.
